(19) United States
(12) Patent Application Publication
(10) Pub. No.: US 2026/0205122 A1
(43) Pub. Date: Jul. 16, 2026

(54) Voltage Level Shifting

(71) Applicant: PARADE TECHNOLOGIES, LTD., San Jose, CA (US)

(72) Inventors: WEI-YANG LIN, Taipei (TW); KUO-CHENG HUANG, Taipei (TW); BO-YI KUO, Zhubei City (TW); YUEH-LIN Yang, Zhubei City (TW)

(21) Appl. No.: 18/984,819

(22) Filed: Dec. 17, 2024

(51) Int. Cl. H03K 19/0185; G09G 3/20

(52) U.S. Cl. CPC H03K 19/018528; G09G 3/20; G09G 2310/0289

(57) ABSTRACT

This application is directed to electronic systems, devices, circuits, and methods for voltage level shifting. An electronic device includes a pair of current mirroring transistors, which includes a first mirroring transistor and a second mirroring transistor and is configured to mirror a drive current passing the first mirroring transistor to the second mirroring transistor. A pair of differential input transistors is coupled to the pair of current mirroring transistors, includes a first input transistor and a second input transistor, and is configured to receive at least a first input signal. A first swing-clamped transistor is coupled between the second mirroring transistor and the second input transistor, and a gate and a drain of the first swing-clamped transistor are coupled to each other. A first output stage is coupled to the first swing-clamped transistor and configured to generate a first output signal.

### TECHNICAL FIELD

This application relates to electronic circuit, and in particular integrated circuits, electronic components, electronic devices, electronic systems, and methods for managing voltage signals (e.g., in a display device).

### BACKGROUND

Voltage level shifting is a critical technique in display devices to bridge the gap between components operating at different voltage levels, ensuring compatibility and functionality. Modern displays often incorporate various integrated circuits (ICs), such as microcontrollers, drivers, and signal processors, which may operate at different logic levels (e.g., 1.8V, 3.3V, or 5V). Level shifters translate signals between these voltage domains without compromising signal integrity, enabling seamless communication. In displays like LCDs, OLEDs, or e-ink panels, level shifting is particularly essential for driving pixel electrodes or managing timing control signals, as these elements often require higher voltages than the logic circuits. Efficient level shifting minimizes power loss, reduces electromagnetic interference, and maintains high-speed operation, which is vital for delivering high-quality responsive visual outputs.

### SUMMARY

Various embodiments of this application are directed to electronic circuitry, focusing particularly on the design and implementation of level shifters that operate across multiple voltage domains for use in display devices. The level shifters are used as buffers (e.g., in clock paths or signal processing) when voltage domains of an input signal and an output signal are different. Some implementations of display devices demand low power consumption, low peak conversion current, small circuit area, and low conversion delay time from level shifters. A pair of current mirroring transistors is coupled to a pair of differential input transistors to form two differential input arms and enable a single-ended output signal or dual-ended differential output signals. In some embodiments, a swing-clamped transistor is coupled in one of the two differential input arms. Alternatively, in some embodiments, a startup inverter is coupled between the two differential input arms. By these means, level shifters are formed with small area, low current contention, low power consumption, and balanced rising and falling times, thereby satisfying demands of many display devices.

In one aspect of this application, an integrated circuit includes a pair of current mirroring transistors, a pair of differential input transistors, a first swing-clamped transistor, and a first output stage. The pair of current mirroring transistors is coupled to one another, and includes a first mirroring transistor and a second mirroring transistor. The current mirroring transistors are configured to mirror a drive current passing the first mirroring transistor to the second mirroring transistor. The pair of differential input transistors is coupled to the pair of current mirroring transistors. The input transistors include a first input transistor and a second input transistor, and are configured to receive at least a first input signal. The first swing-clamped transistor is coupled between the second mirroring transistor and the second input transistor. A gate and a drain of the first swing-clamped transistor are coupled to each other. The first output stage is coupled to the first swing-clamped transistor and configured to generate a first output signal.

In one aspect of this application, an integrated circuit includes a pair of current mirroring transistors, a pair of differential input transistors, a first output stage, and a startup inverter. The pair of current mirroring transistors is coupled to one another, and includes a first mirroring transistor and a second mirroring transistor. The current mirroring transistors are configured to mirror a drive current passing the first mirroring transistor to the second mirroring transistor. The pair of differential input transistors is coupled to the pair of current mirroring transistors. The input transistors include a first input transistor coupled to the first mirroring transistor and a second input transistor coupled to a second mirroring transistor, and are configured to receive at least a first input signal, generate a first intermediate signal at a drain of the first input transistor, and generate a second intermediate signal at a drain of the second input transistor. The first output stage is coupled to the second input transistor and configured to generate a first output signal based on the second intermediate signal. The startup inverter is coupled between the drains of the first input transistor and the second input transistor, and configured to receive an input from the drain of the first input transistor and drive the drain of the second input transistor.

In another aspect, a level shifting device includes any of the above integrated circuits. In another aspect, an electronic device includes any of the above integrated circuits. In another aspect, a display device includes any of the above integrated circuits.

In yet another aspect, a method is implemented to provide an integrated circuit. The method includes providing a pair of current mirroring transistors coupled to one another, the current mirroring transistors including a first mirroring transistor and a second mirroring transistor and configured to mirror a drive current passing the first mirroring transistor to the second mirroring transistor; providing a pair of differential input transistors coupled to the pair of current mirroring transistors, the input transistors including a first input transistor and a second input transistor and configured to receive at least a first input signal; providing a first swing-clamped transistor coupled between the second mirroring transistor and the second input transistor, wherein a gate and a drain of the first swing-clamped transistor are coupled to each other; and providing a first output stage coupled to the first swing-clamped transistor and configured to generate a first output signal.

In yet another aspect, a method is implemented to provide an integrated circuit. The method includes providing a pair of current mirroring transistors coupled to one another, the current mirroring transistor including a first mirroring transistor and a second mirroring transistor and configured to mirror a drive current passing the first mirroring transistor to the second mirroring transistor; providing a pair of differential input transistors coupled to the pair of current mirroring transistors, the input transistors including a first input transistor coupled to the first mirroring transistor and a second input transistor coupled to a second mirroring transistor, the input transistors configured to receive at least a first input signal, generate a first intermediate signal at a drain of the first input transistor, and generate a second intermediate signal at a drain of the second input transistor; providing a first output stage coupled to the second input transistor and configured to generate a first output signal based on the second intermediate signal; and providing a startup inverter coupled between the drains of the first input transistor and the second input transistor, the startup inverter configured to receive an input from the drain of the first input transistor and drive the drain of the second input transistor.

Some implementations of this application are directed to a method for converting voltage. The method includes receiving a first input signal at an input of a pair of differential input transistors that includes a first input transistor and a second input transistor. The pair of differential input transistors is further coupled a pair of current mirroring transistors, which is coupled to one another. The current mirroring transistors include a first mirroring transistor and a second mirroring transistor and are configured to mirror a drive current passing the first mirroring transistor to the second mirroring transistor. The first swing-clamped transistor is coupled between the second mirroring transistor and the second input transistor, and a gate and a drain of the first swing-clamped transistor are coupled to each other. The method further includes generating one or more first swing-clamped signals from the first swing-clamped transistor based on the first input signal and generating a first output signal by a first output stage coupled to the first swing-clamped transistor based on the one or more first swing-clamped signals.

Some implementations of this application are directed to a method for converting voltage. The method includes receiving a first input signal at an input of a pair of differential input transistors that includes a first input transistor and a second input transistor. The pair of differential input transistors is further coupled a pair of current mirroring transistors, which is coupled to one another. The current mirroring transistors include a first mirroring transistor coupled to the first input transistor and a second mirroring transistor coupled to the second input transistor, and are configured to mirror a drive current passing the first mirroring transistor to the second mirroring transistor. The method further includes generating a first output signal by a first output stage coupled to the second input transistor based on the second intermediate signal. The method further includes forcing a startup of the pair of differential input transistors by a startup inverter coupled between drains of the first input transistor and the second input transistor, including receiving an input from a drain of the first input transistor and driving a drain of the second input transistor.

These illustrative embodiments are mentioned not to limit or define the disclosure, but to provide examples to aid understanding thereof. Additional embodiments are discussed in the Detailed Description, and further description is provided there.

### BRIEF DESCRIPTION OF DRAWINGS

The disclosed embodiments have other advantages and features, which will be more readily apparent from the detailed description, the appended claims, and the accompanying figures (or drawings). A brief introduction of the figures is below.

FIG. 1 is a block diagram of an electronic system, in accordance with some embodiments.

FIG. 2 is a block diagram illustrating a touch panel display subsystem having a scalable intra-panel interface (SIPI) between a touch-integrated timing controller (TTCON) and touch-embedded source drivers (TSDs), in accordance with some embodiments.

FIG. 3 is a block diagram of a touch panel display subsystem having a TTCON and TSDs, in accordance with some embodiments.

FIG. 4 is schematic diagram of an example display pixel driven by a display electrode and a common electrode in a display driving state, in accordance with some implementations.

FIG. 5 is a schematic diagram of an example level shifter circuit that applies a swing-clamped transistor and generates a single-ended output signal, in accordance with some embodiments.

FIGS. 6A and 6B are schematic diagrams of another example level shifter circuit that applies a startup inverter and generates a single-ended output signal, in accordance with some embodiments.

FIG. 7 is a schematic diagram of an example level shifter circuit that applies N-type current mirroring transistors and P-type differential input transistors, in accordance with some embodiments.

FIGS. 8A and 8B schematic diagrams of example level shifter circuits each of which applies a pair of swing-clamped transistors and generates a double-ended differential output signal, in accordance with some embodiments.

FIG. 9A is a flow diagram of an example method for providing an electronic device including a level shifting circuit, in accordance with some embodiments.

FIG. 9B is a flow diagram of another example method for providing an electronic device including a level shifting circuit, in accordance with some embodiments.

FIG. 10A is a flow diagram of an example method for converting voltage signals, in accordance with some embodiments.

FIG. 10B is a flow diagram of another example method for converting voltage signals, in accordance with some embodiments.

Like reference numerals refer to corresponding parts throughout the several views of the drawings.

### DETAILED DESCRIPTION

The figures and the following description relate to embodiments by way of illustration only. It should be noted that from the following discussion, alternative embodiments of the structures and methods disclosed herein will be readily recognized as viable alternatives that may be employed without departing from the principles of what is claimed.

Reference will now be made in detail to several embodiments, examples of which are illustrated in the accompanying figures. It is noted that wherever practicable similar or like reference numbers may be used in the figures and may indicate similar or like functionality. The figures depict embodiments of the disclosed system (or method) for purposes of illustration only. One skilled in the art will readily recognize from the following description that alternative embodiments of the structures and methods illustrated herein may be employed without departing from the principles described herein.

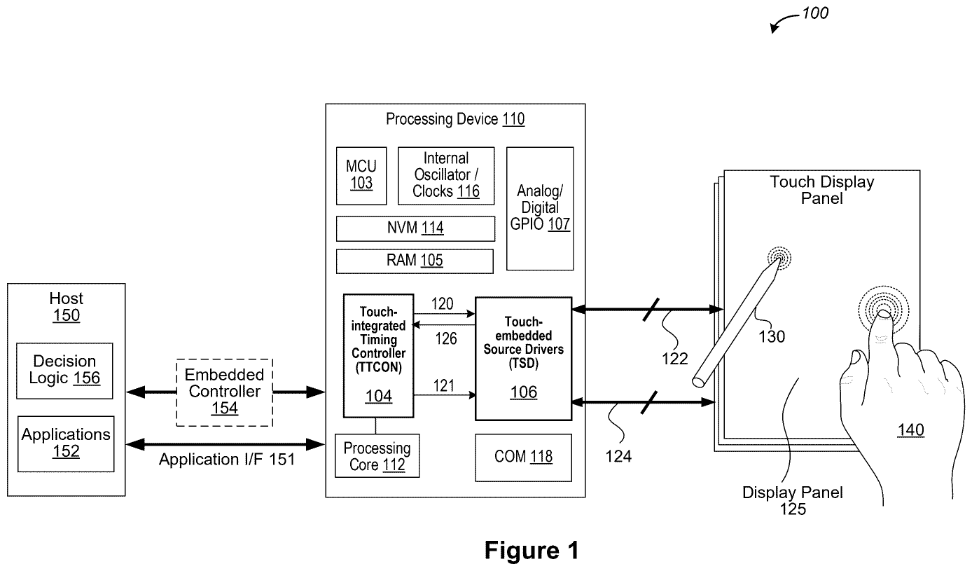

FIG. 1 is a block diagram of an electronic system 100, in accordance with some embodiments. In the electronic system 100, a processing device 110 is electrically coupled to a display panel 125 including a display pixel array. The display pixel array further includes a plurality of display pixels, a plurality of control lines, and a plurality of data lines. Each display pixel is powered between a display power supply and a ground supply. The processing device 110 operates in a display driving mode in which a drive voltage is generated to drive a data line of each display pixel to enable display of a corresponding color on the respective display pixel with a respective luminance level. In some embodiments, the processing device 110 includes a processing core 112 that provides display information (e.g., display content data of a sequence of image frames) to a touch-integrated timing controller (TTCON) 104 and touch-embedded source drivers (TSDs) 106, such that the TSDs 106 can drive individual display pixels in the display panel 125 to display images or video clips based on the display information. In some embodiments, the processing core 112 includes some or all functions of the TTCON 104 and TSDs 106 (i.e., part or all of the TTCON 104 and TSDs 106 is integrated in the processing core 112). Further, in the depicted embodiment, the display pixel array of the display panel 125 is coupled to the processing device 110 via a bus 124, and configured to receive display driving signals (e.g., the drive voltages) from the processing device 110 via the bus 124. More specifically, the display driving signals are generated by the TSDs 106 of the processing device 110 and provided to the display panel 125 via the bus 124.

In some embodiments, the display panel 125 further includes a touch sense array (e.g., a capacitive sense array), and the processing device 110 can also operate in a touch sensing mode in addition to the display driving mode. Optionally, the touch sense array is formed on the same layer of electrically conductive material that coats the bottom surface of the top encapsulation layer and provides electrodes for the display pixel array. Optionally, the touch sense array is formed on an alternative layer of conductive material that is distinct from the layer of electrically conductive material providing the common electrodes for the display pixel array. The processing device 110 is configured to measure capacitance variations at the touch sense array and detect one or more touches proximate to a surface of the display panel 125. In some embodiments, the processing device 110 alternates between the display driving mode and the touch sensing mode according to a predetermined duty cycle (e.g., 80% in the display driving mode) for the display driving mode, and detects a contact with or a proximity to a touch sensing surface associated with the display pixel array without interfering with display operations of the display pixel array. Conversely, in some embodiments, the processing device 110 operates in the display driving mode and in the touch sensing mode independently of each other via the display pixel array and touch sense array, respectively.

In the touch sensing mode, capacitive touch sensors in the touch sense array may be used to allow the TSDs 106 of the processing device 110 to measure self-capacitance, mutual capacitance, or any combination thereof. In the depicted embodiment, the touch sense array is coupled to the processing device 110 via a bus 122, and configured to provide touch sense signals to the TSDs 106 of the processing device 110 via the bus 122. By these means, the processing device 110 detects the presence of a touch object 140, the presence of a stylus 130, or any combination thereof on the touch sense array. In an example, the touch object is an active stylus 130. The active stylus 130 operates as a timing master, and the processing device 110 adjusts the timing of the touch sense array to match that of the active stylus 130.

In some embodiments, the processing device 110 includes analog and/or digital general purpose input/output (“GPIO”) ports 107. The GPIO ports 107 may be programmable. The GPIO ports 107 may be coupled to a Programmable Interconnect and Logic (“PIL”), which acts as an interconnect between the GPIO ports 107 and a digital block array of the processing device 110 (not shown). In some embodiments, the digital block array is configured to implement a variety of digital logic circuits (e.g., DACs, digital filters, or digital control systems) using configurable user modules (“UMs”). The digital block array may be coupled to a system bus. The processing device 110 may also include memory, such as random access memory (“RAM”) 105 and non-volatile memory (“NVM”) 114. The RAM 105 may be static RAM (“SRAM”). The non-volatile memory 114 may be flash memory, which may be used to store firmware (e.g., control algorithms executable by the processing core 112 to implement operations described herein). The processing device 110 may also include a memory controller unit (“MCU”) 103 coupled to the memory and to the processing core 112. The processing core 112 is a processing element configured to execute instructions or perform operations. The processing device 110 may include other processing elements as would be appreciated by one of ordinary skill in the art having the benefit of this disclosure. It should also be noted that the memory may be internal to the processing device 110 or external to it. In the case of the memory being internal, the memory may be coupled to a processing element, such as the processing core 112. In the case of the memory being external to the processing device 110, the processing device 110 is coupled to the other device in which the memory resides as would be appreciated by one of ordinary skill in the art having the benefit of this disclosure. Some or all of the operations of the processing core 112 may be implemented in firmware, hardware, software, or some combination thereof.

In some embodiments, the touch-integrated timing controller (TTCON) 104 coupled to the processing core 112 is configured to generate a touch control signal 120 and a display drive signal 121. The touch control signal 120 and display drive signal 121 are applied to the TSDs 106 to detect touch locations and drive individual display pixels, respectively. Specifically, the touch control signal 120 is used to enable the touch sensing mode in which self or mutual capacitance of touch sensors of the touch sense array is optionally scanned by the TSDs 106. Touch data 126 are returned from the TSDs 106 to the TTCON 104. One or more touch locations are thereby detected if one or more objects touch a touch sensing surface of the electronic system 100. Alternatively, in some embodiments, the display drive signal 121 includes display content data and display control data, and is used to enable the display driving mode. In such a display driving mode, the TSDs 106 provide a drive voltage to each display pixel of the display pixel array based on the display content data. The display pixel displays an intended color with a certain luminance level upon receiving the drive voltage.

Optionally, the touch control signal 120 and the display drive signal 121 are time-multiplexed, and transmitted from the TTCON 104 to the TSDs 106 via the same forward link. Optionally, the touch control signal 120 and the display drive signal 121 are transmitted from the TTCON 104 to the TSDs 106 via distinct and different forward links, and thereby, processed by the TSDs 106 independently of each other (e.g., during two separate durations of time, concurrently during the same duration of time). As such, in some embodiments, an intra-panel communication interface between the TTCON 104 and TSDs 106 includes a set of display forward links, a set of touch forward links, and a set of backward links.

The processing device 110 may also include an analog block array (not shown) (e.g., a field-programmable analog array). The analog block array is also coupled to the system bus. An analog block array may be configured to implement a variety of analog circuits (e.g., ADCs or analog filters) using, in some embodiments, configurable universal machines. The analog block array may also be coupled to the GPIO 107.

The processing device 110 may include internal oscillator/clocks 116 and a communication block (“COM”) 118. In some embodiments, the processing device 110 includes a spread-spectrum clock (not shown). The oscillator/clocks 116 provides clock signals to one or more of the components of processing device 110. The communication block 118 may be used to communicate with an external component, such as an application processor 152, via an application interface (“I/F”) line 151. In some embodiments, the processing device 110 may also be coupled to an embedded controller 154 to communicate with the external components, such as a host 150. In some embodiments, the processing device 110 is configured to communicate with the embedded controller 154 or the host 150 to send and/or receive data.

The processing device 110 may reside on a common carrier substrate such as, for example, an integrated circuit (“IC”) die substrate, a multi-chip module substrate, or the like. In some embodiments, the components of the processing device 110 may be one or more separate integrated circuits and/or discrete components. In some embodiments, the processing device 110 may be one or more other processing devices known by those of ordinary skill in the art, such as a microprocessor or central processing unit, a controller, a special-purpose processor, a digital signal processor (“DSP”), an application specific integrated circuit (“ASIC”), a field programmable gate array (“FPGA”), or the like.

It is also noted that the embodiments described herein are not limited to having a configuration of a processing device coupled to an application processor, but may include a system that measures the capacitance on the touch sense array and sends the raw data to a host computer 150 where it is analyzed by an application. In effect, the processing that is done by the processing device 110 may also be done in the application processor. Specifically, in some embodiments, instead of performing the operations of the processing core 112 in the processing device 110, the processing device 110 may send the raw data or partially-processed data to the host 150. The host 150, as illustrated in FIG. 1, may include decision logic 156 that performs some or all of the operations of the processing core 112. Operations of the decision logic 156 may be implemented in firmware, hardware, software, or a combination thereof. The host 150 may include a high-level Application Programming Interface (API) in applications 152 that perform routines on the received data, such as compensating for sensitivity differences, other compensation algorithms, baseline update routines, start-up and/or initialization routines, interpolation operations, or scaling operations. The operations described with respect to the processing core 112 may be implemented in the decision logic 156, the applications 152, or in other hardware, software, and/or firmware external to the processing device 110. In some other embodiments, the processing device 110 is the host 150.

Each of the TTCON 104 and TSDs 106 may be integrated into the IC of the processing device 110, or in a separate IC that is optionally disposed in proximity to the display panel 125. In some embodiments, descriptions of the TTCON 104 and TSDs 106 may be generated and compiled for incorporation into other integrated circuits. For example, behavioral level code describing the TTCON 104 or TSDs 106, or portions thereof, may be generated using a hardware descriptive language, such as VHDL or Verilog, and stored to a machine-accessible medium (e.g., CD-ROM, hard disk, floppy disk, or flash memory). Furthermore, the behavioral level code can be compiled into register transfer level (“RTL”) code, a netlist, or a circuit layout and stored to a machine-accessible medium. The behavioral level code, the RTL code, the netlist, and the circuit layout may represent various levels of abstraction to describe the TTCON 104 or TSDs 106.

It is noted that the components of the electronic system 100 may include all of the components described above. In some embodiments, the electronic system 100 includes fewer than all of the components described above. In some embodiments, the electronic system 100 is used in a tablet computer. In some embodiments, the electronic device is used in other applications, such as a desktop computer, a notebook computer, a mobile handset, a personal data assistant (“PDA”), a keyboard, a television, a remote control, a monitor, a handheld multi-media device, a handheld media (audio and/or video) player, a handheld gaming device, a signature input device for point of sale transactions, an eBook reader, a global position system (“GPS”), or a control panel. The embodiments described herein are not limited to touch screens or touch-sensor pads for notebook embodiments.

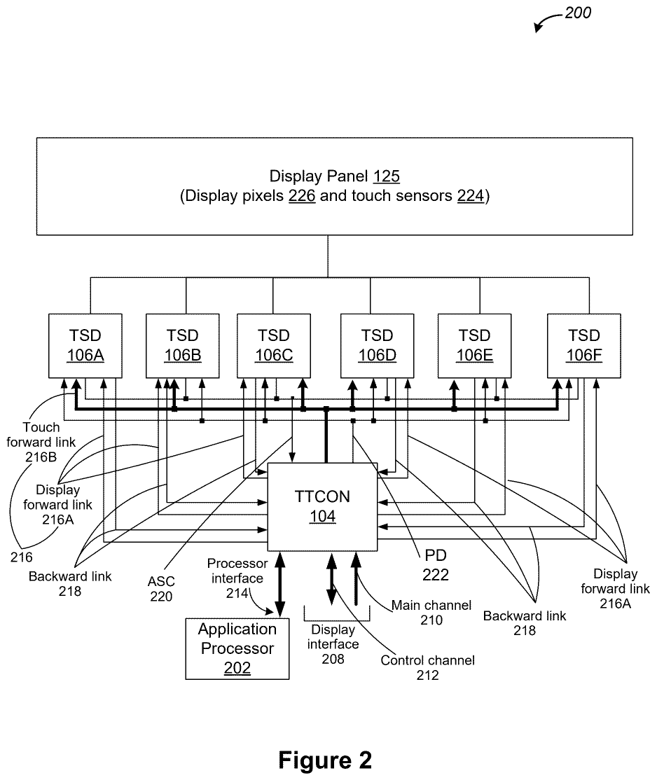

FIG. 2 is a block diagram illustrating a touch panel display subsystem 200 including a scalable intra-panel interface (SIPI) between a touch-integrated timing controller (TTCON) 104 and touch-embedded source drivers (TSDs) 106, in accordance with some embodiments. The touch panel display subsystem 200 includes one or more of: the TTCON 104, the one or more TSDs 106, a plurality of forward links 216, a set of backward links 218, an auxiliary status channel (ASC) 220, a power management bus (PD) 222, a plurality of touch sensors 224, and a plurality of display pixels 226. The TTCON 104 receives display content data and control data from a source device (e.g., a processing core 112 in FIG. 1), and generates a display drive signal and a touch control signal to provide the display content data and control data to TSDs 106. The TTCON 104 includes a display interface 208 for receiving the display content data and control data. The plurality of forward links 216 and the set of backward links 218 form a bi-directional (SIPI) between the TTCON 104 and the TSDs 106 of the touch panel display subsystem 200.

The display interface 208 receives the display content data from the source device for display on the display panel 125. The display content data may include one or more combination of video, image data, and audio data of various formats. The control data received via the display interface 208 includes address, timing, and other control information used by the TTCON 104 to control the operation of the TSDs 106 or send display status data 126 from one or more TSDs 106 to the TTCON 104. In an example, a TSD 106 is embodied in an integrated circuit, die, or computing device included within a system that includes the touch panel display subsystem 200. In another example, a TSD 106 is part of an external computing system, such as a set-top box, digital video disk player, or other external computing device that generates display content data and control data suitable to be received by the TTCON 104 over the display interface 208. In some embodiments, the display interface 208 is included in a graphics processing unit (GPU).

In some embodiments, the display interface 208 includes a main channel 210 and a control channel 212. The main channel 210 carries the display content data for display on the display panel. The control channel 212 carries the control data that is associated with the display content data and transferred via bi-directional communication between each of the TSDs 106 and the TTCON 104. Example control data includes training information, and test and debug information. The control channel 212 also carries status information, including data error rate as measured at one or a combination of the TSD 106 and the TTCON 104. In some embodiments, the control channel 212 carries the display control data used by the display drive signal 121, and the display control data includes one or more of: vertical timing signals (e.g., vertical sync (VSYNC) or frame pulse (FP)), horizontal timing signals (e.g., horizontal sync (HSYNC) or line pulse (LP)), and global timing signals (e.g., display refresh signals for refreshing a displayed image, clock signals for operating gate drivers, and clock and latch enable for operating TSDs 106).

The processor interface 214 of the TTCON 104 supports bi-directional communication between an application processor 202 and the TTCON 104. The application processor 202 supports applications running in an operating system environment. Example applications include applications displaying content on the display panel 125 for interaction with a user. For example, the application processor 202 interprets actions associated with interactions with content displayed in the display panel. Example actions may include navigation, content selection, or any other suitable action interacting with the display content. In some embodiments, the application processor 202 is combined with the display interface 208. For example, the application processor 202 may be embedded in the GPU core having a display interface 208. In some embodiments, the TTCON 104 receives application data from the application processor 202 via the processor interface 214 and transmits touch sensor data received from one or more TSDs 106 to the application processor 202 for further processing. In some embodiments, the TTCON 104 receives one or more touch controller commands from an external processor via the processor interface 214 to regulate the transmission of touch data 120 from the TSDs 106 to the TTCON 104.

The ASC 220 of the TTCON 104 is a single line communication link that enables the TSDs 106 to provide status information to the TTCON 104. Example status information includes link information such as symbol lock status or symbol error count. The ASC 220 is shared by multiple TSDs 106 through a multi-drop configuration. In some embodiments, a single ASC 220 connects all of the TSDs 106 in the touch panel display subsystem to a single TTCON 104. In another embodiment, multiple ASCs 220 may be used, with each ASC 220 connected to a subset of TSDs 106. In addition, multiple TTCONs 104 may be used to communicate with TSDs through multiple ASCs 220.

The PD 222 of the TTCON 104 enables the TTCON 104 to send power control information to control the operation state of the TSDs 106.

The SIPI of the TTCON 104 includes a plurality of forward links 216 and a set of backward links 218. Each of the links 216 and 218 operates in accordance with an SIPI standard. The plurality of forward links 216 transmits display content data and control data from the TTCON 104 to each TSD 106. The plurality of forward links 216 includes one or more data channels, each data channel embodied as a differential pair of conductors. In some embodiments, the one or more data channels are AC or DC-coupled differential pairs with double termination. In some embodiments, the number of data channels included in the forward links 216 is scalable. In an example, the plurality of forward links 216 includes two data channels. The number of data channels may be greater than two to satisfy the maximum transmission throughput used for a specific implementation of the touch panel display subsystem 200.

Further, the plurality of forward links 216 includes a first subset of display forward links 216A and a second subset of touch forward links 216B for the purposes of transmitting display-related data and control signals separately from touch-related control signals. That said, the first subset of display forward links 216A is used to transmit a display drive signal 121 including display content data and display control data, and the second subset of touch forward links 216B is used to transmit a touch control signal 120, independently of the display forward links 216A. Each display forward link is coupled between the TTCON 104 and a respective TSD 106A to provide distinct display content data and control data to the respective TSD 106A. In contrast, in some embodiments, the set of touch forward links 216B is a point to point communication link for touch forward links coupled between the TTCON 104 and the TSDs 106 to provide the TSDs 106 with the same touch control signal 120.

In some embodiments, each backward link 218 includes a single differential pair of signal conductors that transmit touch data from each TSD 106 to the TTCON 104. In some embodiments, the digital data transmitted over each backward link 218 includes touch data 126 (e.g., touch-related confirmation data, status data, touch sensor data) received from the touch sensors 224. In some embodiments, each backward link 218 has similar and identical electrical characteristics to each of the forward links 216.

Each TSD 106 receives multi-bit digital display content data and control data from the TTCON 104 via the forward links 216, converts the display content data to analog voltage levels, and provides the analog voltage levels to pixels in the display panel 125. The transmission path formed by the output of each TSD 106 to the input of each pixel in a specific column of pixels is referred to herein as an output channel or channel. A TSD 106 includes multiple output buffers, where each output buffer operates to rapidly charge the column line capacitance of the corresponding channel. The TSD 106 also receives touch sensor data from one or more touch sensors 224 and sends the received touch sensor data to the TTCON 104 via the respective backward link 218 for further processing. In some embodiments, a group of TSDs 106 is coupled to a single touch sensor 224.

Each touch sensor 224 measures physical interactions with a portion of the display panel and obtains information describing location, position, force, and interaction duration information of the physical interaction with the display panel. For example, when an object (e.g., a finger) touches the display panel, the touch sensor 224 measures an analog signal indicating the physical interaction, and the analog signal is converted into digital data (i.e., touch data 126), in a corresponding TSD 106. The touch data 126 is then transmitted to the TTCON 104 over a corresponding backward link 218 for further processing. Touch information can be extracted in the TTCON 104 from the touch data 126. Example touch information includes position of a touch event relative to reference point on the display panel 125, force applied on the display panel 125, and touching duration indicating the duration of the touch event. The touch sensor 224 may employ well-known methods, including resistive and capacitive elements to detect a touch event. In some embodiments, the touch sensors 224 are integrated with a transparent touch-sensitive material disposed on the display panel. Alternatively, the touch sensors 224 may be integrated into the display panel 125. The number of touch sensors 224 varies based on the size of a display area and a size of each touch sensor. Each touch sensor 224 is coupled to a group of column drivers that are placed physically in proximity to the touch sensor 224.

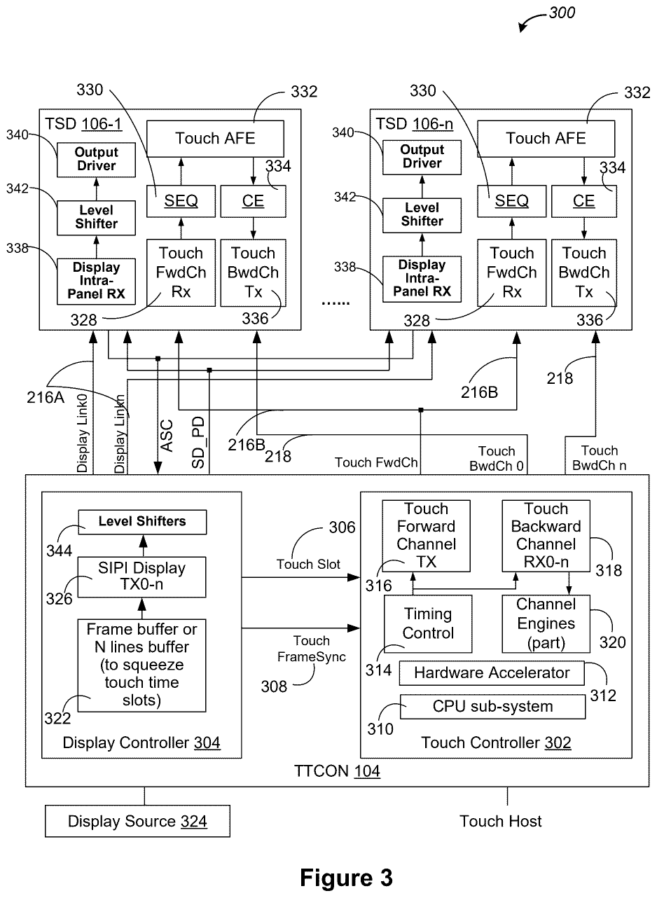

FIG. 3 is a block diagram of a touch panel display subsystem 300 having a TTCON 104 and a plurality of TSDs 106, in accordance with some embodiments. The TTCON 104 and TSDs 106 are coupled to each other via an intra-panel interface including at least a set of display forward links 216A, a set of touch forward links 216B, and a set of backward links 218. Specifically, the TTCON 104 is coupled to each TSD 106 via a display forward link 216A, a touch forward link 216B, and a backward link 218. For each TSD 106, the display forward link 216A is configured to transmit a display drive signal 121 including display content data and display control data. For each TSD 106, the touch forward link 216B is distinct from the display forward link 216A and configured to transmit a touch control signal 120 including an instruction to initiate an operation mode on the one or more TSDs or the plurality of touch sensors 224, and the backward link 218 is configured to return the touch data 126 generated according to the operation mode to the TTCON 104. The display drive signal 121 transmitted via the display forward link 216A and the touch data 126 returned via the backward link 218 are distinct for each TSD 106, and therefore, each of the display forward link 216A and backward link 218 is a point-to-point link. In some embodiments, each touch forward link 216B is a point-to-point link. Alternatively, in some embodiments, the touch control signal 120 is address aware and each TSDs 106 has address assigned, and the touch forward link 216B is a multi-drop link connecting the TTCON 104 to all TSDs 106.

The touch forward link 216B is used to deliver touch configuration, touch timing control, and touch power control. For example, the touch control signal 120 passed by the touch forward link 216B is used to enable functions including, but are not limited to, dividing a touch receiver clock for a touch clock, dividing self synchronization by a dedicated k-code, synchronizing operations of the touch sensors 224 and active stylus 130, synchronizing a touch clock divider, reading the touch data 126, configuring a touch analog frontend (AFE) (e.g., a touch AFE 332 in FIG. 3), and providing a touch backward channel clock source. In contrast, the touch data 126 collected via the backward link 218 includes, but is not limited to, touch sensor data, data concerning a touch forward link quality, a debug status, and a touch forward link lock/unlock indicator.

In some embodiments, commands, configurations and instructions/requests are sent by the TTCON 104 through the forward links 216 only. From a system control perspective, the TTCON 104 is a master, and the TSDs 106 are slaves subject to the control of the TTCON 104.

The TTCON 104 includes a touch controller 302 and a display controller 304 configured to control the TSDs 106 to measure touch sense data from the touch sensors 224 and drive the display pixels 226, respectively. In some embodiments, display driving and touch sensing are synchronized, e.g., time-multiplexed with respective duty cycles. The display controller 304 sends a touch slot signal 306 or a touch frame synchronization signal 308 to synchronize itself with the touch controller 302 based on a slot or an image frame, respectively. Optionally, each slot corresponds to a short duration of time separating two rows of display content data, and touch sensing is implemented in the short duration of time. A complete scan of the touch sensors 224 is conducted in a single slot or a plurality of slots separating multiple rows of display content data.

The touch controller 302 includes a CPU sub-system 310, a hardware accelerator 312, a timing control module 314, a touch forward channel transmitter 316, a plurality of touch backward channel receivers 318, and a channel engine 320. The CPU subs-system 310, hardware accelerator 312, and channel engines 320 are collectively called a touch sensing engine. A touch control signal 120 is generated by the timing control module 314, and sends to the TSDs 106 via the touch forward channel transmitter 316. Touch data 126 returned by the TSDs 106 are received by the touch backward channel receivers 318, and provided to channel engine 320 for further processing, e.g., identifying one or more touch events on different areas of a touch sensing surface of the display panel 125.

The touch forward channel transmitter 316 is coupled to a touch forward channel receiver 328 of each TSD 106, and configured to transmit the touch control signal 120 to the touch forward channel receiver 328, e.g., in a serial data format. Each TSD 106 further includes a deserialization module 330, a touch AFE 332, a channel engine 334, and a touch backward channel transmitter 336. The deserialization module 330 is configured to convert the touch control signal 120 to internal touch control signals or recover a touch clock signal locally. The internal touch control signals and the touch clock signal are used to control the touch AFE 332 to measure touch sense data from the touch sensors 224 in the display panel 125, e.g., scanning a subset or all touch sensors 224. The touch sense data is captured by the touch AFE 332 and pre-processed in the channel engine 334 before it is passed to the touch backward channel transmitter 336. The touch backward channel transmitter 336 is coupled to a respective touch backward channel receiver 318 of the touch controller 302 via a respective backward link 218, thereby returning the touch sense data to the touch controller 302 via the respective backward link 218.

In contrast, the display controller 304 of the TTCON 104 includes a buffer unit 322 (e.g., a frame buffer or a plurality of line buffers) and a plurality of display intra-panel transmitters 326. The buffer unit 322 is configured to store display content data received from a display source 324 in frame or in line. The display intra-panel transmitters 326 are configured to extract the display content data in the frame buffer or line buffers 322 and send the display content data to the display forward links 216A coupled to the TSDs 106. On the TSD side, each TSD 106 has a display intra-panel receiver 338 coupled to a respective display forward link 216A and configured to receive a subset of display content data corresponding to the respective TSD 106. A display output driver 340 is configured to receive the subset of display content data from the display intra-panel receiver 338 and drive a subset of the display pixels 226 using the subset of display content data, thereby allowing still images or video clips associated with the display content data to be displayed on the display panel 125.

In some embodiments, one or more level shifters 342 are coupled to, or included in, the display output driver 340. The one or more level shifters 342 are configured to convert an input signal varying between two input supply levels to an output signal varying between two output supply levels, and at least one of the two input supply levels is different from the two output supply levels. In an example (e.g., associated with TFT LCDs), a difference between the two output voltage supply levels of the display output driver 340 may be equal to 10V to 15V, for controlling pixel gate drivers, requiring level shifters to step up signals from lower voltage logic levels (e.g., 5V). Alternatively, in some embodiments, one or more level shifters 344 are coupled at an output of the display controller 304 or an input of a TSD 106. For example, the display controller 304 operate at 3.3V logic, and the TSD 106 requires 5V logic for proper operation. In this case, the level shifter 344 is configured to convert the 3.3V signals from the display controller 304 to 5V signals for the TSD 106 and vice versa, ensuring bidirectional communication.

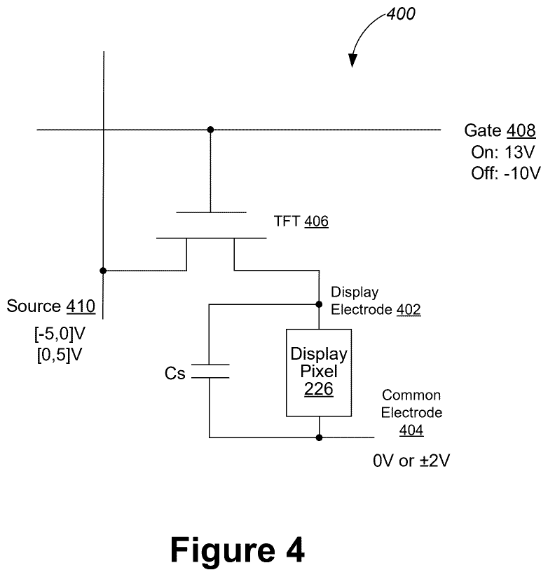

FIG. 4 is a schematic diagram of an example display pixel circuit 400 for driving a display pixel 226 in a display driving state, in accordance with some implementations. The display pixel 226 is disposed between a display electrode 402 and a common electrode 404. A first TFT 406 is connected between a respective row line (e.g., a gate line 408) and a respective column line (e.g., a source line 410), and configured to provide a first electrical signal to drive the display electrode 402 of the corresponding display pixel 226. In the case of LCD display pixels, the first electrical signal and another second electrical signal are applied onto the display electrode 402 and common electrode 404, respectively, and therefore, to liquid crystal molecules corresponding to the display pixel 226. The molecules tend to untwist from their original twisted form, and cause a change in an angle of an incident light, thereby causing display of a color at a location corresponding to the display pixel 226.

The first TFT 406 is formed on a glass substrate to drive the display electrode 402 that is formed on the same glass substrate. More specifically, a gate layer, a semiconductor layer, a source/drain layer, one or more conductive layers, and one or more intervening insulating layers are deposited on the glass substrate. These material layers are lithographically patterned on the glass substrate to form functional part (e.g., gate, source and drain) of the first TFT 406 as well as the row (gate) line 408 and the column (source) line 410 of the first TFT 406. The first TFT 406 is configured to receive display driving signals from the processing device 110 (more specifically, the pixel drive circuit 102 of the processing device 110), and generates the first electrical signal to drive the display electrode 402 of the display pixel 226.

In some implementations, the display pixel 226 includes a second TFT to generate the second electrical signal to drive the common electrode 404. The second TFT is formed on the glass substrate to drive the common electrode 404 that is formed on the same glass substrate. A gate layer, a semiconductor layer, a source/drain layer, one or more conductive layers, and one or more intervening insulating layers are deposited. These material layers are lithographically patterned on the glass substrate to form functional part (e.g., gate, source and drain) of the second TFT as well as a row (gate) line and a column (source) line of the second TFT. The second TFT is configured to receive the display driving signals from the processing device 110 (more specifically, the pixel drive circuit 102 of the processing device 110), and generates the second electrical signal to drive the common electrode 404 of the display pixel 226.

In an example, in the display driving state, the common electrode 404 is coupled to the ground (e.g., 0V) or another reference voltage (e.g., 2V and −2 V). The gate line 408 is coupled to a TFT turn-on voltage V_{GH} (e.g., 13V) to turn on the first TFT 406, such that the display electrode 402 is electrically driven by an electrical signal delivered to the source line 410 of the first TFT 406. Optionally, the electrical signal of the source line 410 has a magnitude of +5V or −5V, and the first electrical signal applied on the display electrode 402 tracks the electrical signal of the source line 410. In another example, the common electrode 404 is coupled to the ground (e.g., 0V). The gate line 408 is coupled to a TFT turn-off voltage VGL (e.g., −10V) to turn off the first TFT 406, such that the display electrode 402 is electrically decoupled from the electrical signal delivered to the source of the TFT 406. Regardless of the magnitude of the electrical signal the source line 410 has, the first electrical signal at the display electrode 402 does not track the electrical signal of the source line 410. In some embodiments, the common electrode 404, the gate line 408, or the source line 410 of the display pixel 226 is driven by an output driver 340, and the output driver 340 is coupled to, or includes, a level shifter that is configured to convert an input signal to an output signal, wherein the input signal (e.g., a control signal of 0-1.8V) and the output signal (a source voltage of 0-5V) vary between different voltage rails.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

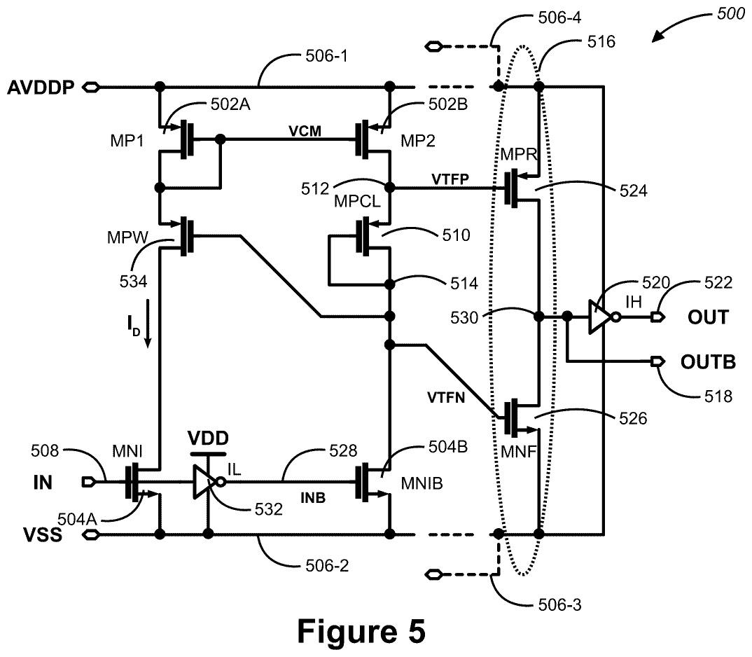

FIG. 5 is a schematic diagram of an example level shifter circuit 500 that applies a swing-clamped transistor 510 and generates a single-ended output signal 518, in accordance with some embodiments. In some embodiments, the level shifter circuit 500 is applied in a display device to drive one or more display pixels 226 (FIG. 4) and TFT 406, a.k.a. gate driver. The level shifter circuit 500 includes a pair of current mirroring transistors 502A and 502B and a pair of differential input transistors 504A and 504B. The current mirroring transistors 502A and 502B are coupled to one another and a first power rail 506-1, include a first mirroring transistor 502A and a second mirroring transistor 502B, and are configured to mirror a drive current Ip passing the first mirroring transistor 502A to the second mirroring transistor 502B. The differential input transistors 504A and 504B are coupled to the current mirroring transistors 502A and 502B and a second power rail 506-2. The input transistors 504A and 504B include a first input transistor 504A and a second input transistor 504B, and are configured to receive at least a first input signal 508. In some embodiments, a transistor size of the first input transistor 504A is substantially equal to a transistor size of the second input transistor 504B, and a transistor size of the first mirroring transistor 502A is substantially equal to a transistor size of the second mirroring transistor 504B.

In some embodiments, the level shifter circuit 500 further includes a first swing-clamped transistor 510 coupled between the second mirroring transistor 502B and the second input transistor 504B. A gate and a drain of the first swing-clamped transistor 510 are coupled to each other (e.g., includes a diode-connected transistor), and the first swing-clamped transistor 510 is configured to output two first swing-clamped signals 512 and 514 based on the first input signal 508. A first output stage 516 is coupled to the first swing-clamped transistor 510, and configured to generate a first output signal 518 based on the two first swing-clamped signals 512 and 514. In some embodiments, an inverting buffer 520 is coupled to the first output stage 516, and configured to generate an inverted output signal 522 based on the first output signal 518. The first output signal 518 and the inverted output signal 522 may form a pair of differential output signals.

In some embodiments, each of the input transistors 504A and 504B includes a respective N-type transistor, and each of the current mirroring transistors 502A and 502B and the first swing-clamped transistor 510 includes a respective P-type transistor. In some embodiments, the first mirroring transistor 502A is coupled to the first input transistor 504A to form a first differential input arm of the level shifter circuit 500, and the second mirroring transistor 502B is coupled to the second input transistor 504B to form a second differential input arm.

In some embodiments, the first input signal 508 is configured to vary between two input supply levels (e.g., 0 and 1.8V), and at least one of the two input supply levels is different from supply levels of both of the first power rail 506-1 (e.g., 5V) and the second power rail 506-2 (e.g., 0 V), which may be lower than the first power rail 506-1 in FIG. 5.

In some embodiments, the first output stage 516 includes two first output transistors 524 and 526. The two first output transistors 524 and 526 are configured to receive the two first swing-clamped signals 512 and 514 at respective gates and output the first output signal 518 at a common output node 530. In some embodiments, the first output stage 516 is also called a dual-input inverter output stage. In some embodiments, the two first output transistors 524 and 526 include a P-type transistor 524 and an N-type transistor 526. In some embodiments, the first output stage 516 is coupled between the first power rail 506-1 and the second power rail 506-2. Alternatively, in some embodiments, while the first and second differential input arms are coupled between the power rails 506-1 and 506-2, the first output stage 516 is coupled between the first power rail 506-1 and a third power rail 506-3, and the third power rail 506-3 has a distinct and different power supply voltage from the second power rail 506-2. Alternatively, in some embodiments, while the first and second differential input arms are coupled between the power rails 506-1 and 506-2, the first output stage 516 is coupled between a fourth power rail 506-4 and the second power rail 506-2, and the fourth power rail 506-4 has a distinct and different power supply voltage from the first power rail 506-1.

In some embodiments, the first input transistor 504A is configured to receive the first input signal 508, and the second input transistor 504B is configured to receive a second input signal 528 that is complementary to the first input signal 508. The first input signal 508 and the second input signal 528 form a pair of differential input signals. Alternatively, in some embodiments, an input inverter 532 is coupled between gates of the first input transistor 504A and the second input transistor 504B. The input inverter 532 is configured to generate a second input signal 528 based on the first input signal 508. The first input signal 508 and the second input signal 528 are applied to drive two distinct gates of the first input transistor 504A and the second input transistor 504B. Further, in some embodiments, the input inverter 532 operates in an input voltage range (e.g., between the second power rail 506-2 and an input power rail VDD, 0-1.8V). The input voltage range is smaller than an output voltage range (e.g., between the power rails 506-1 and 506-2, 0-5V).

In some embodiments, the level shifter circuit 500 further includes a switching transistor 534 coupled between the first mirroring transistor 502A and the first input transistor 504A. A gate and a drain of the first swing-clamped transistor 510 are coupled to a gate of the switching transistor 534. In some embodiments, the pair of current mirroring transistors 502A and 502B and the switching transistor 534 forming a Wilson current mirror. In some embodiments, the pair of current mirroring transistors 502A and 502B, the first swing-clamped transistor 510, and the switching transistor 534 form an improved Wilson current mirror.

In some embodiments, the first swing-clamped transistor 510 has a transistor size configured to define an operating range on a voltage transfer curve when a transition occurs. The first input voltage 508 has an input voltage range, and when the first input signal 508 increases or decreases to the transition voltage, the first output voltage 518 may be substantially equal to the transition voltage. Stated another way, the transistor size of the first swing-clamped transistor 510 is adjusted to select an operating point of the level shifter circuit 500, allowing the level shifter circuit 500 to have balanced rising and falling times. In some embodiments, the transition voltage has a higher sensitivity to the transistor size of the first swing-clamped transistor 510 compared with transistor sizes of the output transistors 524 and 526, allowing adjustment of performance of the level shifter circuit 500 more conveniently.

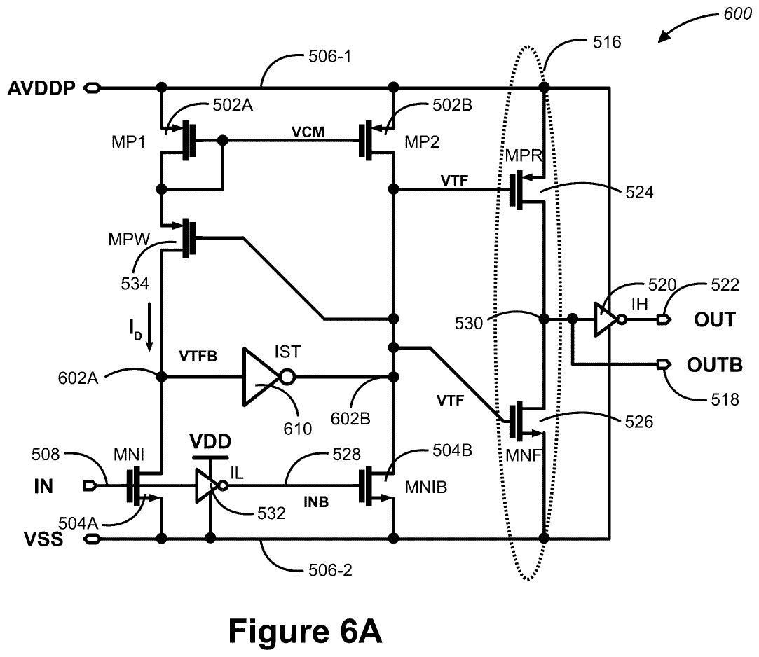

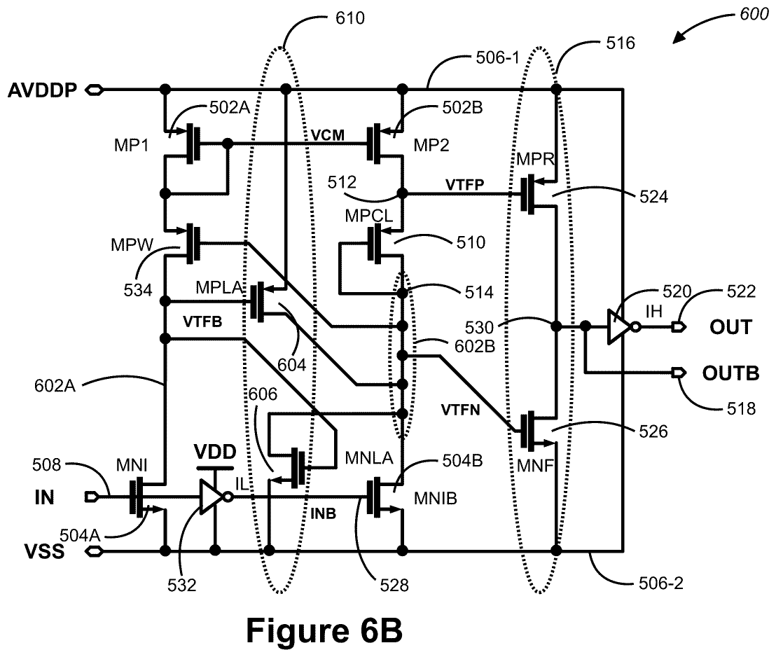

FIGS. 6A and 6B are schematic diagrams of another example level shifter circuit 600 that applies a startup inverter 610 and generates a single-ended output signal 518, in accordance with some embodiments. In some embodiments, the level shifter circuit 600 is applied in a display device to drive one or more display pixels 226 (FIG. 4) and TFT 406, a.k.a. gate driver. The level shifter circuit 600 includes a pair of current mirroring transistors 502A and 502B and a pair of differential input transistors 504A and 504B. The current mirroring transistors 502A and 502B include a first mirroring transistor 502A and a second mirroring transistor 502B, and the differential input transistors 504A and 504B include a first input transistor 504A coupled to the first mirroring transistor 502A and a second input transistor 504B coupled to the second mirroring transistor 502B. The input transistors 504A and 504B are configured to receive at least a first input signal 508, generate a first intermediate signal 602A at a drain of the first input transistor 504B, and generate a second intermediate signal 602B at a drain of the second input transistor 504B. A first output stage 516 is coupled to the second input transistor 504B and configured to generate a first output signal 518 based on the second intermediate signal 602B. Stated another way, in some embodiments, the level shifter circuit 600 does not include the first swing-clamped transistor 510, and the two first swing-clamped signals 512 and 514 merge to the second intermediate signal 602B.

In some embodiments, the level shifter circuit 600 further includes the startup inverter 610 coupled between the drains of the first input transistor 504A and the second input transistor 504B. The startup inverter 610 is configured to receive an input (e.g., the first intermediate signal 602A) from the drain of the first input transistor and drive the drain of the second input transistor. In some situations, during circuit startup, when the first input signal 508 & 528 are unknown, 504A and 504B cannot be guaranteed whether they are turned on, 602B also becomes unknown. Therefore, the voltage of 602B may cause 524 and 526 to be turned on simultaneously, resulting in large leakage. The second intermediate signal 602B is promptly pulled up or down by the startup inverter 610 without waiting for the input inverter 532 or the first and second input transistor 504A 504B. This prevents the second intermediate signal 602B from being unknown during circuit startup, thereby preventing the output transistors 524 and 526 from leaking current. Avoiding a large amount of leakage can reduce the energy consumption of the power management IC (PMIC) and reduce the over current protection (OCP) of the PMIC that is triggered due to excessive current during startup., and therefore, is particularly important in display device products.

In some embodiments, the level shifter circuit 600 further includes a switching transistor 534 coupled between the first mirroring transistor 502A and the first input transistor 504A. A gate of the switching transistor 534 is coupled to a drain of the second input transistor 504B. In some embodiments, the pair of current mirroring transistors 502A and 502B and the switching transistor 534 forming a Wilson current mirror.

Referring to FIG. 6B, in some embodiments, the level shifter circuit 600 includes both the startup inverter 610 and the first swing-clamped transistor 510. The first swing-clamped transistor 510 is a diode-connected transistor providing two first swing-clamped signals 512 and 514, which are applied to drive the output transistors 524 and 526, respectively. The swing-clamped signal 514 corresponds to the second intermediate signal 602B. The start inverter 610 is coupled between the first power rail 506-1 and the second power rail 506-2, and includes a P-type transistor 604 and an N-type transistor 606. Gates of the transistors 604 and 606 are coupled to each other and configured to receive the first intermediate signal 602A, and drains of the transistors 604 and 606 are coupled to each other and configured to drive the second intermediate signal 602B.

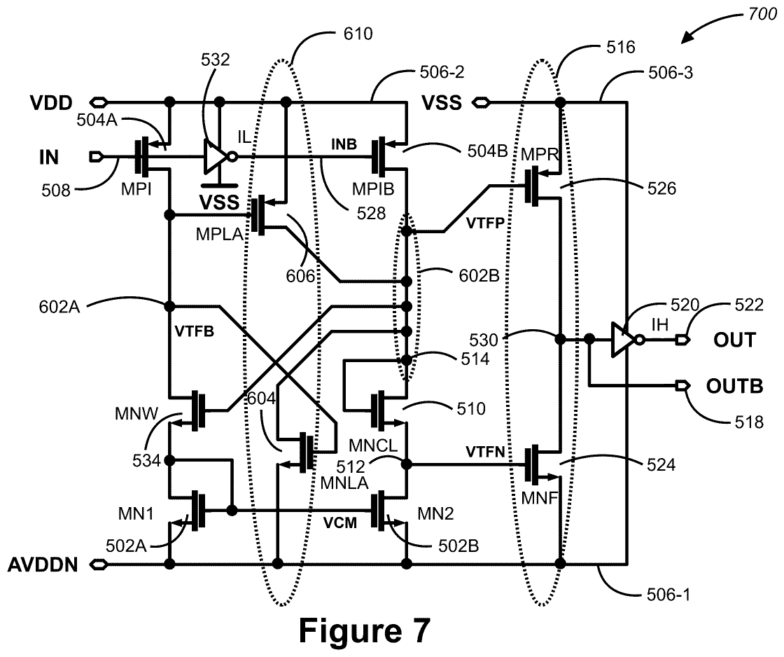

FIG. 7 is a schematic diagram of an example level shifter circuit 700 that applies N-type current mirroring transistors 502A and 502B and P-type differential input transistors 504A and 504B, in accordance with some embodiments. The level shifter circuit 700 applies a swing-clamped transistor 510, a startup inverter 610, or both, and generates a single-ended output voltage 518. In some embodiments, the level shifter circuit 700 is applied in a display device to drive one or more display pixels 226 (FIG. 4) (TFT gate driver). The level shifter circuit 700 includes a pair of current mirroring transistors 502A and 502B and a pair of differential input transistors 504A and 504B. The current mirroring transistors 502A and 502B include a first mirroring transistor 502A and a second mirroring transistor 502B, and the differential input transistors 504A and 504B include a first input transistor 504A coupled to the first mirroring transistor 502A on a first differential input arm and a second input transistor 504B coupled to the second mirroring transistor 502B on a second differential input arm. A first output stage 516 is coupled to the second differential input arm, and configured to generate a first output signal 518, e.g., based on the two first swing-clamped signals 512 and 514.

In some embodiments, the level shifter circuit 700 further includes a first swing-clamped transistor 510 (e.g., a diode-connected transistor) coupled between the second mirroring transistor 502B and the second input transistor 504B. In some embodiments, the level shifter circuit 700 further includes a switching transistor 534 coupled between the first mirroring transistor 502A and the first input transistor 504A. In some embodiments, the level shifter circuit 700 further includes a startup inverter 610 coupled between the drains of the first input transistor 504A and the second input transistor 504B. The startup inverter 610 is configured to receive an input (e.g., the first intermediate signal 602A) from the drain of the first input transistor and drive the drain of the second input transistor.

Referring to FIG. 7, in some embodiments, each of the input transistors 504A and 504B includes a respective P-type transistor, and each of the current mirroring transistors 502A and 502B, the first swing-clamped transistor 510 (if applied), and the switching transistor 534 (if applied) includes a respective N-type transistor. The first differential input arm and the second differential input arm of the level shifter circuit 700 are coupled between the first power rail 506-1 and the second power rail 506-2 higher than the first power rail 506-1. The first power rail 506-1 has a rail voltage lower than that of the second power rail 506-2. In some embodiments, the first output stage 516 is coupled between the first power rail 506-1 and a third power rail 506-3, and the third power rail 506-3 has a distinct and different power supply voltage from the second power rail 506-2. Alternatively, in some embodiments not shown, the first output stage 516 is coupled between a fourth power rail and the second power rail 506-2, and the fourth power rail has a distinct and different power supply voltage from the first power rail 506-1.

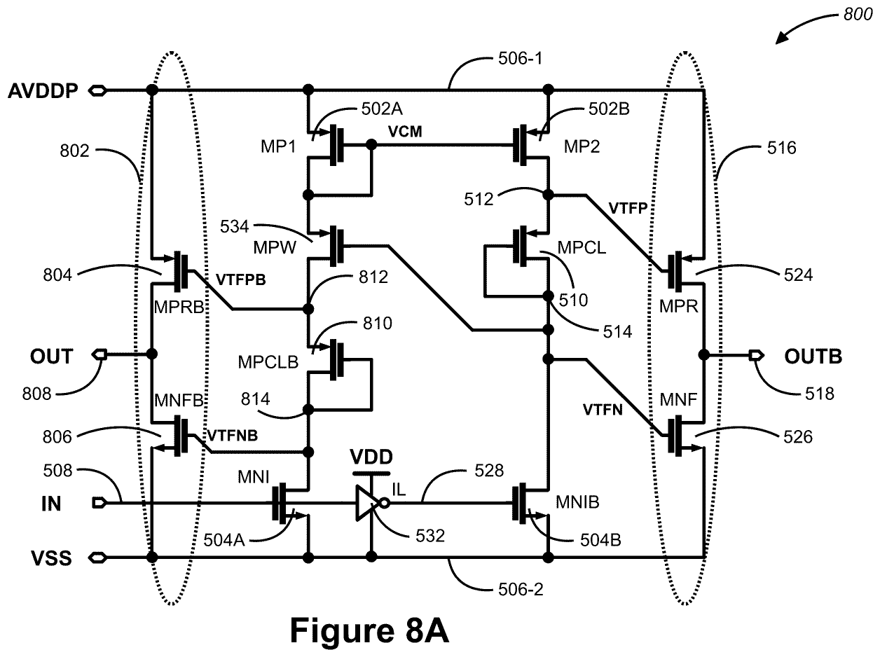

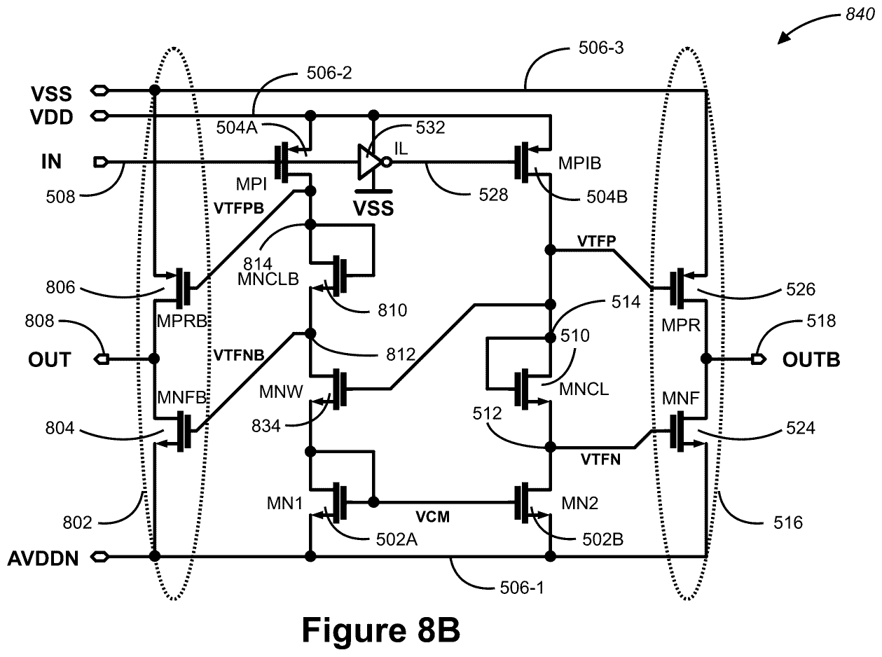

FIGS. 8A and 8B schematic diagrams of example level shifter circuits 800 and 840 each of which applies a pair of swing-clamped transistors 510 and 810 and generates a double-ended differential output signal, in accordance with some embodiments. In some embodiments, the level shifter circuit 800 is applied in a display device to drive one or more display pixels 226 (FIG. 4) (TFT GATE DRIVER). The level shifter circuit 800 includes a pair of current mirroring transistors 502A and 502B and a pair of differential input transistors 504A and 504B. The current mirroring transistors 502A and 502B include a first mirroring transistor 502A and a second mirroring transistor 502B, and the differential input transistors 504A and 504B include a first input transistor 504A coupled to the first mirroring transistor 502A on a first differential input arm and a second input transistor 504B coupled to the second mirroring transistor 502B on a second differential input arm.

The level shifter circuit 800 further includes a first swing-clamped transistor 510 (e.g., a diode-connected transistor) coupled between the second mirroring transistor 502B and the second input transistor 504B on the second differential input arm. A first output stage 516 is coupled to the second differential input arm, and configured to generate a first output signal 518, e.g., based on the two first swing-clamped signals 512 and 514. Referring to FIG. 8, in some embodiments, the level shifter circuit 800 further includes a second swing-clamped transistor 810 (e.g., a diode-connected transistor) coupled between the first mirroring transistor 502A and the first input transistor 504A on the first differential input arm. The second swing-clamped transistor 810 is configured to output two second swing-clamped signals 812 and 814 based on the first input signal 508. A second output stage 802 is coupled to the first differential input arm, includes output transistors 804 and 806, and is configured to generate a second output signal 808, e.g., based on the two second swing-clamped signals 812 and 814. The first output signal 518 and the second output signal 808 may form a double-ended differential output signal.

In some embodiments, the first differential input arm of the level shifter circuit 800 further includes a switching transistor 534 coupled between the first mirroring transistor 502A and the second swing-clamped transistor 810. A gate of the first swing-clamped transistor 510 is coupled to the gate of the switching transistor 534. In some embodiments, the pair of current mirroring transistors 502A and 502B and the switching transistor 534 forming a Wilson current mirror. In some embodiments, the pair of current mirroring transistors 502A and 502B, the first swing-clamped transistor 510, and the switching transistor 534 form an improved Wilson current mirror.

In some embodiments, the swing-clamped transistor 510 and 810 have transistor sizes configured to define operating ranges on voltage transfer curves when a transition occurs and adjust a rising time and a falling time of each output signal 518 or 808. In some embodiments, transistor sizes of the output transistors 524, 526, 804, and 806 are configured to define the voltage transfer curves and adjust a rising time and a falling time of each output signal 518 or 808. Stated another way, the transistor sizes of the swing-clamped transistor 510 and 810 and/or the output transistors 524, 526, 804, and 806 are adjusted to select an operating point of the level shifter circuit 800, allowing the level shifter circuit 800 to have balanced rising and falling times. In some embodiments, the transition voltage has a higher sensitivity to the transistor size of the first swing-clamped transistor 510 compared with transistor sizes of the output transistors 524 and 526, enhancing performance of the level shifter circuit 800 easier.

In some embodiments, the second output stage 802 includes two second output transistors 804 and 806, and the two second output transistors 804 and 806 are configured to receive the two second swing-clamped signals 812 and 814 at their respective gates and output the second output signal 808 at a respective common node of the two second output transistors 804 and 806. Further, in some embodiments, the first output stage 516 includes two first output transistors 524 and 526, and a size of each of two first output transistors 524 and 526 is different from a size of a respective one of the two second output transistors 804 and 806. For example, output transistor 524 and 804 are P-type transistors and have different transistor sizes, and output transistor 526 and 806 are N-type transistors and have different transistor sizes.

Referring to FIG. 8A, in some embodiments, each of the input transistors 504A and 504B and the output transistors 526 and 806 includes a respective N-type transistor, and each of the current mirroring transistors 502A and 502B, the swing-clamped transistor 510 and 810 (if applied), the switching transistor 534 (if applied), and the output transistors 524 and 804 includes a respective P-type transistor. In some embodiments, the first differential input arm and the second differential input arm of the level shifting circuit 840 are biased between the first power rail 506-1 and the second power rail 506-2 lower than the first power rail 506-1. The output stages 516 and 802 are also biased between the first power rail 506-1 and the second power rail 506-2. For example, the first power rail 506-1 has a positive rail voltage (e.g., 3V, 5V, 10V), and the second power rail 506-2 is grounded. The first input signal 508 is a digital control signal between the second power rail 506-2 and an input power rail VDD (e.g., in a range of [0, 1.8V]), and shifted to generated the output signals 518 and 808 between the first power rail 506-1 and the second power rail 506-2 (e.g., in a range of [0, 4 to 8V] or [−8to −4 V, 0] for driving a source line 410, in a range of [0, 12 to 20V] or [−20V to −12 V, 0] for driving a gate line 408).

Referring to FIG. 8B, in some embodiments, each of the input transistors 504A and 504B and the output transistors 526 and 806 includes a respective P-type transistor, and each of the current mirroring transistors 502A and 502B, the swing-clamped transistor 510 and 810 (if applied), the switching transistor 534 (if applied), and the output transistors 524 and 804 includes a respective N-type transistor. In some embodiments, the first differential input arm and the second differential input arm of the level shifting circuit 840 are biased between the first power rail 506-1 and the second power rail 506-2 higher than the first power rail 506-1. The output stages 516 and 802 are biased between the first power rail 506-1 and a third power rail 506-3 distinct from the second power rail 506-2. For example, the first power rail 506-1 has a negative rail voltage (e.g., −3V, −5V, −10V). The second power rail 506-2 is a positive rail voltage (e.g., 1.8V), and the third power rail 506-3 is grounded. the first input signal 508 is a digital control signal between the second power rail 506-2 and the third power rail 506-3 (e.g., in a range of [0, 1.8V]), and shifted to generated the output signals 518 and 808 between the first power rail 506-1 and the third power rail 506-3 (e.g., in a range of (e.g., in a range of [0, 4 to 8V] or [−8to −4 V, 0] for driving a source line 410, in a range of [0, 12 to 20V] or [−20V to −12 V, 0] for driving a gate line 408).

It should be understood that details of level shifter circuits described herein with respect to any one of FIGS. 5-8B are also applicable in an analogous manner to level shifter circuits described with respect to any other figures of FIGS. 5-8B. For brevity, these details are not repeated here.

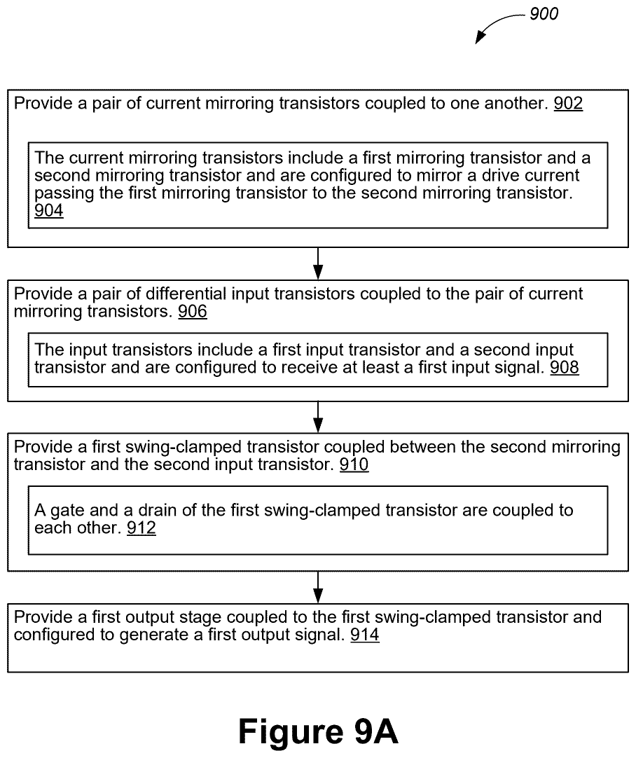

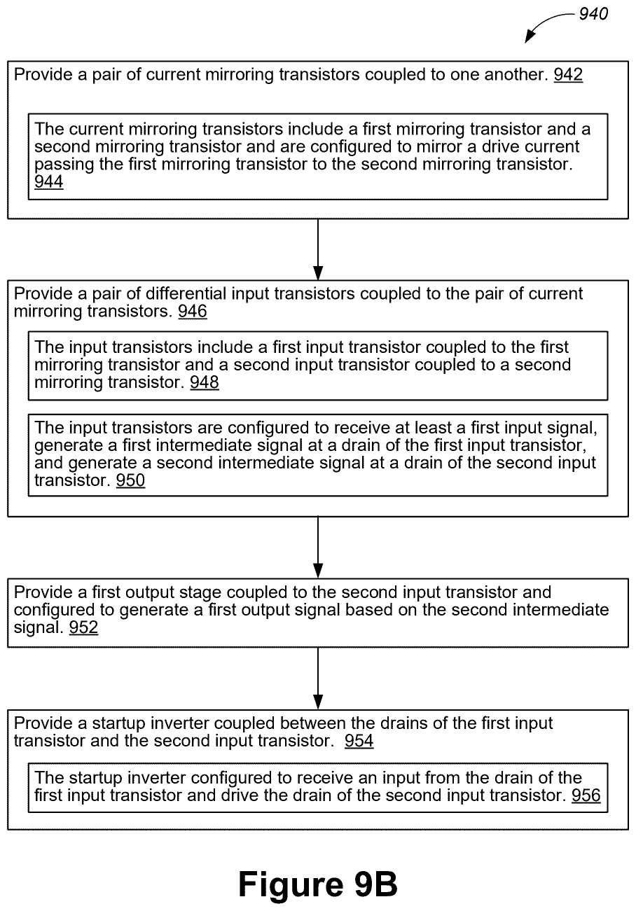

FIG. 9A is a flow diagram of an example method 900 for providing an electronic device including a level shifting circuit, in accordance with some embodiments. The method 900 includes providing (operation 902) a pair of current mirroring transistors 502A and 502B coupled to one another. The current mirroring transistors 502A and 502B includes (operation 904) a first mirroring transistor 502A and a second mirroring transistor 502B and configured to mirror a drive current passing the first mirroring transistor 502A to the second mirroring transistor 502B. The method 900 includes providing (operation 906) a pair of differential input transistors 504A and 504B coupled to the pair of current mirroring transistors 502A and 502B. The input transistors 504A and 504B include (operation 908) a first input transistor 504A and a second input transistor 504B and configured to receive at least a first input signal 508 (e.g., at a gate of an input transistor 504A or 504B). The method 900 includes providing (operation 910) a first swing-clamped transistor 510 (e.g., in FIG. 5) coupled between the second mirroring transistor 502B and the second input transistor 504B. A gate and a drain of the first swing-clamped transistor 510 are coupled (operation 912) to each other. The first swing-clamped transistor 510 may be configured to output two first swing-clamped signals 512 and 514 generated based on the first input signal 508. The method 900 includes providing (operation 914) a first output stage 516 (e.g., in FIG. 5) coupled to the first swing-clamped transistor 510 and configured to generate a first output signal 518, e.g., based on the two first swing-clamped signals 512 and 514.

In some embodiments, the first mirroring transistor 502A is coupled to the first input transistor 504A on a first differential input arm, and the second mirroring transistor 502B is coupled to the second input transistor 504B on a second differential input arm. The pair of current mirroring transistors 502A and 502B is coupled to a first power rail 506-1, and the pair of differential input transistors is coupled to a second power rail 506-2. Further, in some embodiments, the first output stage 516 is coupled between the first power rail 506-1 and the second power rail 506-2. Alternatively, in some embodiments, the first output stage 516 is coupled between the first power rail 506-1 and a third power rail 506-3 (FIG. 7). The third power rail 506-3 has a distinct and different power supply voltage from the second power rail 506-2.

In some embodiments, the first input signal 508 is configured to vary between two input supply levels, and at least one of the two input supply levels is different from supply levels of both of the first power rail 506-1 and the second power rail 506-2.

In some embodiments, the method 900 further includes providing a startup inverter 610 coupled between a drain of the first input transistor 504A and the drain of the second input transistor 504B, the startup inverter 610 configured to receive an input (e.g., a first intermediate signal 602A in FIG. 6A) from the drain of the first input transistor 504A and drive the drain of the second input transistor 504B based on the input.

In some embodiments, the method 900 further includes providing an inverting buffer 520 (FIG. 5) coupled to the first output stage 516 and configured to generate an inverted output signal 522 based on the first output signal 518.

In some embodiments, the first input transistor 504A is configured to receive the first input signal 508, and the second input transistor 504B is configured to receive a second input signal 528 that is complementary to the first input signal 508.

In some embodiments, the method 900 further includes providing an input inverter 532 (FIG. 5) coupled between gates of the first input transistor 504A and the second input transistor 504B, and the input inverter 532 configured to generate a second input signal 528 based on the first input signal 508 to drive one of the first input transistor 504A and the second input transistor 504B.

In some embodiments, each of the input transistors 504A and 504B includes a respective P-type transistor, and each of the current mirroring transistors 502A and 502B and the first swing-clamped transistor 510 includes a respective N-type transistor.

In some embodiments, each of the input transistors 504A and 504B includes a respective N-type transistor, and each of the current mirroring transistors 502A and 502B and the first swing-clamped transistor 510 includes a respective P-type transistor.

In some embodiments, the first swing-clamped transistor 510 has a transistor size configured to provide a operation range on a voltage transfer curve when transition occurs.

In some embodiments, the method 900 further includes providing a switching transistor 534 coupled between the first mirroring transistor 502A and the first input transistor 504A, wherein a gate of the first swing-clamped transistor 510 is coupled to the gate of the switching transistor 534. Further, in some embodiments, the method 900 further includes providing a second swing-clamped transistor 810 (e.g., in FIGS. 8A and 8B) coupled between the switching transistor 534 and the first input transistor 504A. A gate and a drain of the second swing-clamped transistor 810 are coupled to each other, and the second swing-clamped transistor 810 is configured to output two second swing-clamped signals 812 and 814 based on the first input signal 508. The method 900 further includes providing a second output stage 802 coupled to the second swing-clamped transistor 810 and configured to generate a second output signal 808 based on the two second swing-clamped signals 812 and 814. The first output signal 518 and the second output signal 808 form a differential output signal. Additionally, in some embodiments, the second output stage 802 is coupled between the first power rail 506-1 and the second power rail 506-2 and includes two second output transistors 804 and 806. The two second output transistors are configured to receive the two second swing-clamped signals 812 and 814 at respective gates and output the second output signal 808 at a respective common node of the two second output transistors 804 and 806. In some embodiments, the first output stage 516 includes two first output transistors 524 and 526, and a size of each of two first output transistors 524 and 526 is different from a size of a respective one of the two second output transistors.

In some embodiments, a transistor size of the first input transistor 504A is substantially equal to a transistor size of the second input transistor 504B, and a transistor size of the first mirroring transistor 502A is substantially equal to a transistor size of the second mirroring transistor 502B.

FIG. 9B is a flow diagram of another example method 940 for providing an electronic device including a level shifting circuit, in accordance with some embodiments. The method 940 includes providing (operation 942) a pair of current mirroring transistors 502A and 502B coupled to one another. The current mirroring transistor includes (operation 944) a first mirroring transistor 502A and a second mirroring transistor 502B, and is configured to mirror a drive current passing the first mirroring transistor 502A to the second mirroring transistor 502B. The method 940 includes providing (operation 946) a pair of differential input transistors 504A and 504B coupled to the pair of current mirroring transistors 502A and 502B. The input transistors 504A and 504B include (operation 948) a first input transistor 504A coupled to the first mirroring transistor 502A and a second input transistor 504B coupled to a second mirroring transistor 502B. The input transistors 504A and 504B are configured (operation 950) to receive at least a first input signal 508 (e.g., at a gate of an input transistor 504A or 504B), generate a first intermediate signal 602A at a drain of the first input transistor 504A, and generate a second intermediate signal 602B at a drain of the second input transistor 504B. The method 940 includes providing (operation 952) a first output stage 516 coupled to the second input transistor 504B and configured to generate a first output signal 518 based on the second intermediate signal 602B and providing (operation 954) a startup inverter 610 coupled between the drains of the first input transistor 504A and the second input transistor 504B. The startup inverter 610 is configured (operation 956) to receive an input from the drain of the first input transistor 504A and drive the drain of the second input transistor 504B.

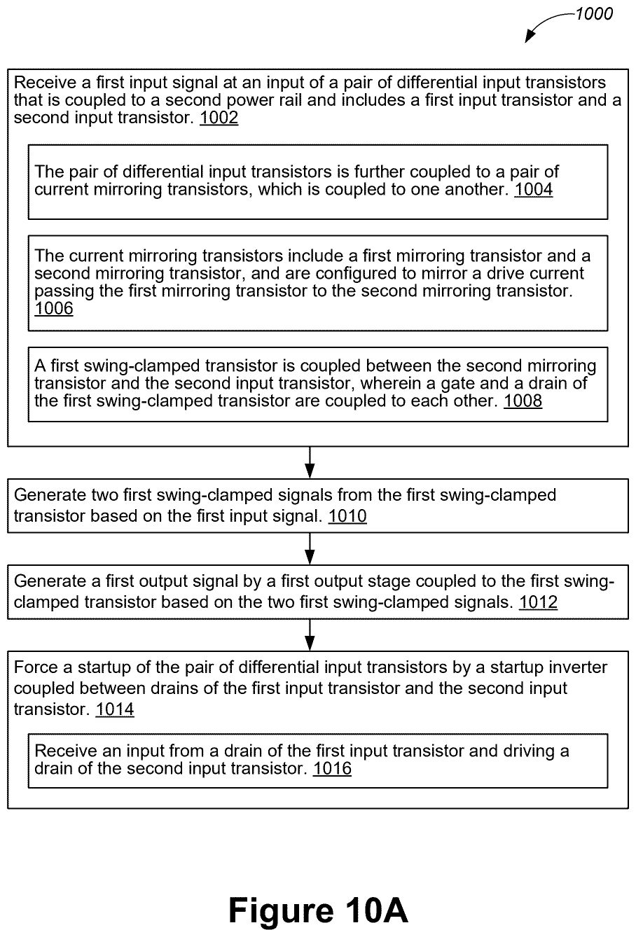

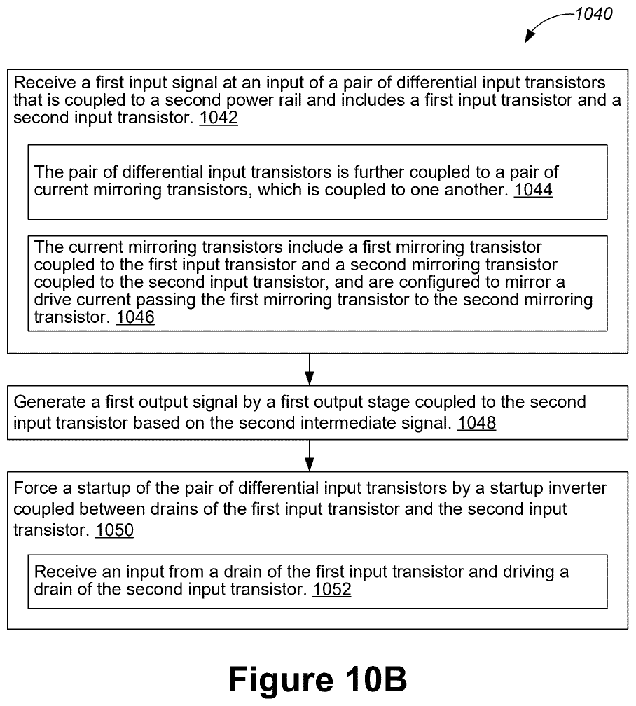

FIG. 10A is a flow diagram of an example method 1000 for converting voltage signals, in accordance with some embodiments. The method 1000 includes receiving (operation 1002) a first input signal 508 at an input of a pair of differential input transistors 504A and 504B that includes a first input transistor 504A and a second input transistor 504B. The pair of differential input transistors 504A and 504B is further coupled (operation 1004) to a pair of current mirroring transistors 502A and 502B, which is coupled to one another. The current mirroring transistors 502A and 502B include (operation 1006) a first mirroring transistor 502A and a second mirroring transistor 502A, and are configured to mirror a drive current passing the first mirroring transistor 502A to the second mirroring transistor 502A. A first swing-clamped transistor 510 is coupled (operation 1008) between the second mirroring transistor 502A and the second input transistor 504B, and a gate and a drain of the first swing-clamped transistor 510 are coupled to each other. The method 1000 further includes generating (operation 1010) one or more first swing-clamped signals (e.g., signals 512 and 514 in FIG. 5) from the first swing-clamped transistor 510 based on the first input signal 508 and generating (operation 1012) a first output signal 518 by a first output stage 516 coupled to the first swing-clamped transistor 510 based on the one or more first swing-clamped signals.

In some embodiments, the method 1000 further includes forcing (operation 1014) a startup of the pair of differential input transistors 504A and 504B by a startup inverter 610 coupled between drains of the first input transistor 504A and the second input transistor 504B, including receiving (operation 1016) an input from a drain of the first input transistor 504A and driving a drain of the second input transistor 504B.

FIG. 10B is a flow diagram of another example method 1040 for converting voltage signals, in accordance with some embodiments. The method 1040 includes receiving (operation 1042) a first input signal at an input of a pair of differential input transistors 504A and 504B that includes a first input transistor 504A and a second input transistor 504B. The pair of differential input transistors 504A and 504B is further coupled (operation 1044) to a pair of current mirroring transistors 502A and 502B, which is coupled to one another. The current mirroring transistors 502A and 502B include (operation 1046) a first mirroring transistor 502A coupled to the first input transistor 504A and a second mirroring transistor 502A coupled to the second input transistor 504B, and are configured to mirror a drive current passing the first mirroring transistor 502A to the second mirroring transistor 502A. The method 1040 further includes generating (operation 1048) a first output signal 518 by a first output stage 516 coupled to the second input transistor 504B based on the second intermediate signal 602B. The method 1040 further includes forcing (operation 1050) a startup of the pair of differential input transistors 504A and 504B by a startup inverter 610 coupled between drains of the first input transistor 504A and the second input transistor 504B, including receiving (operation 1052) an input from a drain of the first input transistor 504A and driving a drain of the second input transistor 504B.

It should be understood that the particular order in which the operations in FIGS. 9A, 9B, 10A, and 10B have been described are merely exemplary and are not intended to indicate that the described order is the only order in which the operations could be performed. One of ordinary skill in the art would recognize various ways to reorder the operations described herein. Additionally, it should be noted that details of other processes described herein with respect to any one of the methods 900, 940, 1000, and 1040 (e.g., FIGS. 9A, 9B, 10A, or 10B) are also applicable in an analogous manner to any other method of the methods 900, 940, 1000, and 1040 (e.g., FIGS. 9A, 9B, 10A, or 10B). It should be noted that details of integrated circuits described with respect to any of FIGS. 1-8B are also applicable in an analogous manner to any of the methods 900, 940, 1000, and 1040 (e.g., FIGS. 9A, 9B, 10A, or 10B). For brevity, these details are not repeated here.

Certain embodiments are described herein as including logic or a number of components, modules, or mechanisms. A hardware module is tangible unit capable of performing certain operations and may be configured or arranged in a certain manner. In example embodiments, one or more computer systems (e.g., a standalone, client or server computer system) or one or more hardware modules of a computer system (e.g., a processor or a group of processors) may be configured by software (e.g., an application or application portion embodied as executable instructions or code) as a hardware module that operates to perform certain operations as described herein.

In various embodiments, a hardware module may be implemented mechanically or electronically. For example, a hardware module may comprise dedicated circuitry or logic that is permanently configured (e.g., as a special-purpose processor, such as a field programmable gate array (FPGA) or an application-specific integrated circuit (ASIC)) to perform certain operations. A hardware module may also comprise programmable logic or circuitry (e.g., within a general-purpose processor or other programmable processor) that is temporarily configured by software to perform certain operations. It will be appreciated that the decision to implement a hardware module mechanically, in dedicated and permanently configured circuitry, or in temporarily configured circuitry (e.g., configured by software) may be driven by cost and time considerations.

The various operations of example methods described herein may be performed, at least partially, by one or more processors that are temporarily configured (e.g., by software) or permanently configured to perform the relevant operations. Whether temporarily or permanently configured, such processors may constitute processor-implemented modules that operate to perform one or more operations or functions. The modules referred to herein may, in some example embodiments, comprise processor-implemented modules.

Some portions of this specification are presented in terms of algorithms or symbolic representations of operations on data stored as bits or binary digital signals within a machine memory (e.g., a computer memory). These algorithms or symbolic representations are examples of techniques used by those of ordinary skill in the data processing arts to convey the substance of their work to others skilled in the art. As used herein, an “algorithm” is a self-consistent sequence of operations or similar processing leading to a desired result. In this context, algorithms and operations involve physical manipulation of physical quantities. Typically, but not necessarily, such quantities may take the form of electrical, magnetic, or optical signals capable of being stored, accessed, transferred, combined, compared, or otherwise manipulated by a machine. It is convenient at times, principally for reasons of common usage, to refer to such signals using words such as “data,” “content,” “bits,” “values,” “elements,” “symbols,” “characters,” “terms,” “numbers,” “numerals,” or the like. These words, however, are merely convenient labels and are to be associated with appropriate physical quantities.

Unless specifically stated otherwise, discussions herein using words such as “processing,” “computing,” “calculating,” “determining,” “presenting,” “displaying,” or the like may refer to actions or processes of a machine (e.g., a computer) that manipulates or transforms data represented as physical (e.g., electronic, magnetic, or optical) quantities within one or more memories (e.g., volatile memory, non-volatile memory, or a combination thereof), registers, or other machine components that receive, store, transmit, or display information.

As used herein any reference to “some embodiments” or “an embodiment” means that a particular element, feature, structure, or characteristic described in connection with the embodiment is included in at least some embodiments. The phrase “in some embodiments” in various places in the specification is not necessarily all referring to the same embodiment.

Some embodiments may be described using the expression “coupled” and “connected” along with their derivatives. For example, some embodiments may be described using the term “coupled” to indicate that two or more elements are in direct physical or electrical contact. The term “coupled,” however, may also mean that two or more elements are not in direct contact with each other, but yet still co-operate or interact with each other. The embodiments are not limited in this context.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

In addition, use of the “a” or “an” are employed to describe elements and components of the embodiments herein. This is done merely for convenience and to give a general sense of the invention. This description should be read to include one or at least one and the singular also includes the plural unless it is obvious that it is meant otherwise.

Upon reading this disclosure, those of skill in the art will appreciate still additional alternative structural and functional designs for a bi-directional scalable intra-panel interface disclosed herein. Thus, while particular embodiments and applications have been illustrated and described, it is to be understood that the disclosed embodiments are not limited to the precise construction and components disclosed herein. Various modifications, changes and variations, which will be apparent to those skilled in the art, may be made in the arrangement, operation and details of the method and apparatus disclosed herein without departing from the spirit and scope described.

1. An integrated circuit, comprising:
a pair of current mirroring transistors coupled to one another, the current mirroring transistors including a first mirroring transistor and a second mirroring transistor and configured to mirror a drive current passing the first mirroring transistor to the second mirroring transistor;
a pair of differential input transistors coupled to the pair of current mirroring transistors, the input transistors including a first input transistor and a second input transistor and configured to receive at least a first input signal;
a first swing-clamped transistor coupled between the second mirroring transistor and the second input transistor, wherein a gate and a drain of the first swing-clamped transistor are coupled to each other;
a switching transistor coupled between the first mirroring transistor and the first input transistor, wherein a gate of the first swing-clamped transistor is coupled to the gate of the switching transistor; and
a first output stage coupled to the first swing-clamped transistor and configured to generate a first output signal.

2. The integrated circuit of claim 1, further comprising a startup inverter coupled between a drain of the first input transistor and the drain of the second input transistor, the startup inverter configured to receive an input from the drain of the first input transistor and drive the drain of the second input transistor based on the input.

3. The integrated circuit of claim 1, wherein the first mirroring transistor is coupled to the first input transistor on a first differential input arm, and the second mirroring transistor is coupled to the second input transistor on a second differential input arm, and wherein the pair of current mirroring transistors is coupled to a first power rail, and the pair of differential input transistors is coupled to a second power rail.

4. The integrated circuit of claim 3, wherein the first output stage is coupled between the first power rail and the second power rail.

5. The integrated circuit of claim 3, wherein the first output stage is coupled between the first power rail and a third power rail and the third power rail has a distinct and different power supply voltage from the second power rail.

6. The integrated circuit of claim 3, wherein the first input signal is configured to vary between two input supply levels, and at least one of the two input supply levels is different from supply levels of both of the first power rail and the second power rail.

7. The integrated circuit of claim 1, wherein the first swing-clamped transistor is configured to output two first swing-clamped signals based on the first input signal, and the first output stage includes two first output transistors that are configured to receive the two first swing-clamped signals at their respective gates and output the first output signal at a respective common node.

8. The integrated circuit of claim 1, further comprising an inverting buffer coupled to the first output stage and configured to generate a second output signal based on the first output signal.

9. The integrated circuit of claim 1, wherein the first input transistor is configured to receive the first input signal, and the second input transistor is configured to receive a second input signal that is complementary to the first input signal.

10. The integrated circuit of claim 1, further comprising:
an input inverter coupled between gates of the first input transistor and the second input transistor, the input inverter configured to generate a second input signal based on the first input signal to drive one of the first input transistor and the second input transistor.

11. The integrated circuit of claim 1, wherein each of the input transistors includes a respective P-type transistor, and each of the current mirroring transistors and the first swing-clamped transistor includes a respective N-type transistor.

12. The integrated circuit of claim 1, wherein each of the input transistors includes a respective N-type transistor, and each of the current mirroring transistors and the first swing-clamped transistor includes a respective P-type transistor.

13. The integrated circuit of claim 1, wherein the first swing-clamped transistor has a transistor size configured to provide a operating range on a voltage transfer curve when transition occurs.

14. (canceled)

15. The integrated circuit of claim 14, further comprising:
a second swing-clamped transistor coupled between the switching transistor and the first input transistor, wherein a gate and a drain of the second swing-clamped transistor are coupled to each other, and the second swing-clamped transistor is configured to output two second swing-clamped signals generated based on the first input signal; and
a second output stage coupled to the second swing-clamped transistor and configured to generate a second output signal based on the two second swing-clamped signals, the first output signal and the second output signal forming a differential output signal.

16. The integrated circuit of claim 15, wherein the second output stage includes two second output transistors, and the two second output transistors are configured to receive the two second swing-clamped signals at respective gates and output the second output signal at a respective common source of the two second output transistors.

17. The integrated circuit of claim 16, wherein the first output stage includes two first output transistors, and a size of each of two first output transistors of the first output stage is different from a size of a respective one of the two second output transistors of the second output stage.

18. The integrated circuit of claim 1, wherein a transistor size of the first input transistor is substantially equal to a transistor size of the second input transistor, and a transistor size of the first mirroring transistor is substantially equal to a transistor size of the second mirroring transistor.

19. An electronic device, comprising:
a pair of current mirroring transistors coupled to one another, the current mirroring transistors including a first mirroring transistor and a second mirroring transistor and configured to mirror a drive current passing the first mirroring transistor to the second mirroring transistor;
a pair of differential input transistors coupled to the pair of current mirroring transistors, the input transistors including a first input transistor and a second input transistor and configured to receive at least a first input signal;
a first swing-clamped transistor coupled between the second mirroring transistor and the second input transistor, wherein a gate and a drain of the first swing-clamped transistor are coupled to each other;
a switching transistor coupled between the first mirroring transistor and the first input transistor, wherein a gate of the first swing-clamped transistor is coupled to the gate of the switching transistor; and
a first output stage coupled to the first swing-clamped transistor and configured to generate a first output signal.

20. A method for converting voltage, comprising:
receiving a first input signal at an input of a pair of differential input transistors that includes a first input transistor and a second input transistor, wherein:
the pair of differential input transistors is further coupled to a pair of current mirroring transistors, which is coupled to one another;
the current mirroring transistors include a first mirroring transistor and a second mirroring transistor, and are configured to mirror a drive current passing the first mirroring transistor to the second mirroring transistor;
a first swing-clamped transistor is coupled between the second mirroring transistor and the second input transistor, wherein a gate and a drain of the first swing-clamped transistor are coupled to each other; and
a switching transistor is coupled between the first mirroring transistor and the first input transistor, wherein the gate of the first swing-clamped transistor is coupled to a gate of the switching transistor;
generating one or more first swing-clamped signals from the first swing-clamped transistor based on the first input signal; and
generating a first output signal by a first output stage coupled to the first swing-clamped transistor based on the one or more first swing-clamped signals.
